(19) United States
(12) Patent Application Publication
(10) Pub. No.: US 2005/0236076 A1
(43) Pub. Date: Oct. 27, 2005

(54) High integrity sputtering target material and method for producing bulk quantities of same

(76) Inventors: Christopher A. Michaluk, Gilbertsville, PA (US); Louis E. Huber JR., Allentown, PA (US); P. Todd Alexander, Berwyn, PA (US)

Correspondence Address: Martha Ann Finnegan, Esq.;Cabot Corporation, Billerica Technical Center, 157 Concord Road, Billerica, MA, 01821-7001, US

(21) Appl. No.: 11/017,224

(22) Filed: Dec. 20, 2004

Related U.S. Application Data
(60) Provisional application No. 60/531,813, filed on Dec. 22, 2003.

(51) Int. Cl. C23C 14/34; C22F 1/00

(52) U.S. Cl. 148/559; 204/298.12; 204/298.13

(57) ABSTRACT

A method of making metal plates as well as sputtering targets is described. In addition, products made by the process of the present invention are further described. The present invention preferably provides a product with reduced or minimized marbleizing on the surface of the metal product which has a multitude of benefits.

This application claims priority under 35 U.S.C. §119(e) of prior U.S. Provisional Patent Application No. 60/531,813 filed Dec. 22, 2003, which is incorporated in its entirety by reference herein.

### BACKGROUND OF THE INVENTION

The present invention relates to metal billets, slabs, rods, and sputter targets. More particularly, the present invention relates to a method of producing a metal having a uniform fine grain size, a homogeneous microstructure, and an absence of surface marbleizing that is useful in making sputter targets and other objects.

Tantalum has emerged as the primary diffusion barrier material for copper interconnects employed in advanced integrated circuit microelectronic devices. During the fabrication sequence of such microelectronic devices, tantalum or tantalum-nitride barrier films are deposited by physical vapor deposition (PVD), a well-established process whereby a source material (termed a “sputtering target”) is eroded by high-energy plasma. Bombardment and penetration of plasma ions into the lattice of the sputtering target causes atoms to be ejected from the surface of the sputtering target which then deposit atop the substrate. The quality of sputter-deposited films is affected by many factors, including the chemistry and metallurgical homogeneity of the sputtering target.

In recent years, research efforts have focused on developing processes to increase the purity, reduce the grain size, and control the texture of tantalum sputtering target materials. For example, U.S. Pat. No. 6,348,113 (Michaluk et al.) and U.S. patent application Ser. No. 2002/0157736 (Michaluk) and Ser. No. 2003/0019746 (Ford et al.), each of which is incorporated herein be reference, describe metalworking processes for attaining select grain sizes and/or preferred orientations in tantalum materials or tantalum sputtering target components through particular combinations of deformation and annealing operations. Each of the cited publications detail process methodologies that are suitable for manufacturing only one or a few tantalum sputtering targets or components; specifically, the publications relate to batch processing of tantalum. Some of the advantages of manufacturing sputtering target components from small work pieces is that the cold working can be done using small mills and presses, material is easily moved and handled within and between work stations, and that the dimensions of the finished part can be tightly controlled using a consistent deformation operation. However, the disadvantages of low-volume manufacturing processes include the intrinsically high variable costs, which include labor and working capital.

A method suitable for producing large lots and bulk quantities of high purity tantalum sputtering targets having microstructural and textural homogeneity is described in U.S. Pat. No. 6,348,113 (Michaluk et al.). While high volume manufacturing processes offer significant cost benefits compared to batch processes, they often cannot achieve tight dimensional tolerances by means of a standardized and repeatable deformation sequence. The mechanical responsiveness of high purity tantalum ingots and heavy rolling slabs is highly variable due to their large, inhomogeneous grain structure. Imposing a predefined and consistent rolling reduction schedule on heavy slabs of high purity tantalum can result in a divergence in plate thickness with each reduction pass, and ultimately would yield plate products having an excessive variation in gauge. Because of this behavior, conventional methods for rolling tantalum plate from heavy slab is to reduce the mill roll gap by a certain amount depending on the width and gauge of the plate, then adding light finishing passes to achieve gauge tolerances typically about +/−10% of the target thickness.

Rolling theory prescribes that heavy reductions per rolling pass are necessary to achieve a uniform distribution of strain throughout the thickness of the component, which is beneficial for attaining a homogeneous annealing response and a fine, uniform microstructure in the finished plate. Scale presents a primary factor that hinders the ability to take heavy rolling reduction when processing high volume tantalum slabs to plate since heavy reduction (e.g., true strain reduction) may represent more of a bite than the rolling mill can handle. This is especially true at the commencement of rolling where the slab or plate thickness is largest. For example, a 0.2 true strain reduction of a 4″ thick slab requires a 0.725″ reduction pass. The separating force that would be necessary to take such a heavy bite would exceed the capability of conventional production rolling mills. Conversely, a 0.2 true strain reduction on a 0.40″ thick plate equates to only a 0.073″ roll reduction, which is well within the capabilities of many manufacturing mills. A second factor that affects the rolling reduction rate of tantalum is the plate width. For a given roll gap per pass, plate gauge, and mill, wider plates will experience a smaller amount of reduction per rolling pass than narrow plates.

Since the processing of bulk tantalum cannot rely solely on heavy rolling reductions to reduce slab to plate, strain is not likely to be uniformly distributed throughout the thickness of the plate. As a result, the product does not evenly respond to annealing, as evidenced by the existence of microstructural and textural discontinuities in tantalum plate as reported in the literature (e.g., Michaluk et al. ″Correlating Discrete Orientation and Grain Size to the Sputter Deposition Properties of Tantalum,” JEM, January, 2002; Michaluk et al., “Tantalum 101: The Economics and Technology of Tantalum,” Semiconductor Inter., July, 2000, both of which are incorporated herein by reference). The metallurgical and textural homogeneity of annealed tantalum plate is enhanced by incorporating intermediate anneal operations to the process as taught by U.S. Pat. No. 6,348,113. However, incorporating one or more intermediate annealing operations during the processing of tantalum plate will also reduce the total strain that is imparted to the final product. This, in turn, would lessen the annealing response of the plate, and hence limit the ability to attain a fine average grain size in the tantalum product.

It is believed by the inventors that the variability in the mechanical response of bulk tantalum is expected to diminish with increasing amounts of cold work. Deformation processing serves to destroy the large grain structure present in the bulk tantalum ingot or rolling slab, whereby the intra-lot and inter-lot variability in the mechanical properties of the high purity tantalum will converge as the gauge of the tantalum is reduced by cold rolling. Therefore, the inventors have discovered a critical deformation point (CDP) that is surpassed during the rolling of tantalum where the variability in mechanical response is sufficiently reduced. Furthermore, as the starting dimensions of all rolling slabs used in high-volume production of tantalum are tightly controlled, the CDP will correlate to a specific gauge of rolled plate. The response of all production material rolled beyond the CDP is believed to be consistent and predictable.

The existence or occurrence of a marbleized structure in tantalum has been deemed to be detrimental to the performance and reliability of tantalum sputtering target material and components. It has only recently been discovered by the inventors that two distinct types of marbleizing can be found in tantalum and other metals: marbleizing observed along the sputtered surface of an eroded tantalum target or component, and marbleizing observed about the as-fabricated surface of the tantalum target or component. In an eroded tantalum sputtering target, marbleizing is formed from the mixture of exposed, sputter-resistant (100) texture bands (that appear as lustrous regions) about the matte finish of the matrix material (created by multi-facet sputter-eroded grains). The propensity for marbling of a sputter-eroded surface is minimized by or eliminated in tantalum sputtering targets or components that are processed to have a homogeneous texture through the thickness of the tantalum target, as described in U.S. Pat. No. 6,348,113. An analytical method for quantifying the texture homogeneity of tantalum sputtering target materials and components is described in U.S. Pat. No. 6,462,339 (Michaluk et al.), which is incorporated herein by reference. Another analytical method for quantifying banding is described in U.S. patent application Ser. No. 60/545,617 filed Feb. 18, 2004 and is incorporated herein by reference.

Surface marbling can be resolved along the as-fabricated surface of wrought tantalum materials or sputtering components after light sputtering (e.g., burn-through trials) or by chemical etching in solutions containing hydrofluoric acid, concentrated alkylides, or fuming sulfuric and/or sulfuric acid, or other suitable etching solutions. In annealed tantalum plate, surface marbleizing appears as large, isolated patches and/or a network of discolored regions atop the acid cleaned, as-rolled surface. The inventors have also determined that the marbleized surface of tantalum can be removed by milling or etching about 0.025″ of material from each surface; however, this approach for eliminating surface marbling is economically undesirable. The current art neither addresses surface marbleizing in tantalum nor teaches means of reducing or eliminating the phenomenon.

Accordingly, a need exists to produce a tantalum (or other metals) sputtering target material or component that is substantially free of surface marbleizing. A further need exists for a manufacturing process suitable for bulk production that results in a sputtering target that is substantially free of surface marbleizing.

### SUMMARY OF THE PRESENT INVENTION

It is therefore a feature of the present invention to provide a valve metal (or other metal) material or sputtering component that is substantially free of surface marbleizing.

Another feature of the present invention is to provide a process for producing bulk quantities of metal materials or sputtering components having a fine, homogeneous microstructure having an average grain size of about 20 microns or less, and a uniform texture through the thickness of the metal material or sputtering component.

Another feature of the present invention is to provide a process for producing bulk quantities of metal materials or sputtering components having consistent chemical, metallurgical, and textural properties within a production lot of product.

Another feature of the present invention is to provide a process for producing bulk quantities of metal materials or sputtering components having consistent chemical, metallurgical, and textural properties between production lots of product.

Another feature of the present invention is to provide a process for producing bulk quantities of metal (e.g., tantalum) materials or sputtering components having consistent chemical, metallurgical, and textural properties within production lots of product.

A further feature of the present invention is to provide a metal (e.g., tantalum) material having microstructural and textural attributes suitable for forming into components including sputtering components and sputtering targets such as those described in Ford, U.S. Published Patent Application No. 2003/0019746, which is incorporated in its entirety by reference herein.

A further feature of the present invention is to provide a formed metal (e.g., tantalum) component including formed sputtering components and sputtering targets having a fine, homogeneous microstructure having an average grain size of about 20 microns or less, and a uniform texture through the thickness of the formed component, sputtering component, or sputtering target that sufficiently retains the metallurgical and textural attributes of the uniformed metal material without the need to anneal the component after forming.

Additional features and advantages of the present invention will be set forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention relates to a method of making a sputtering target. The method involves providing a slab that contains at least one metal (e.g., at least one valve metal) and a first rolling of the slab to form an intermediate plate, wherein the first rolling includes one or more rolling passes. The method further includes dividing the intermediate plate into a plurality of sub-lot plates; and a second rolling of at least one of the sub-lot plates to form a metal plate, wherein the second rolling includes one or more rolling passes, and wherein each of the rolling passes of the second rolling imparts a true strain reduction of greater than about 0.2. The present invention further relates to products made from the process, including sputter targets and other components. The rolling steps can be cold rolling, warm rolling, or hot rolling steps.

It is to be understood that both the foregoing general description and the following detailed description are exemplary and explanatory only and are intended to provide a further explanation of the present invention, as claimed.

The accompanying drawings, which are incorporated in and constitute a part of this application, illustrate some of the embodiments of the present invention and together with the description, serve to explain the principles of the present invention.

### BRIEF DESCRIPTION OF DRAWINGS

FIG. 1 is a drawing relating the dimensions of slab, intermediate plate, and finished plate.

FIGS. 2(a)-(f) are photomicrographs of the transverse section of an annealed tantalum plate showing a uniform grain structure with an average grain size of about 18 microns.

FIG. 3(a)-(b) is an Inverse Pole Figure (IPF) Orientation Map of the transverse section of an annealed tantalum plate showing a homogeneous mixed (111) (100) texture that is sufficiently void of texture bands.

FIG. 4 is a photograph of an etched tantalum plate exhibiting surface marbleizing.

FIG. 5 is a photograph of an etched tantalum plate processed in accordance to the present invention showing an absence of surface marbleizing.

### DETAILED DESCRIPTION OF THE PRESENT INVENTION

The present invention relates to methods and metal products useful in a number of technologies, including the thin films area (e.g., sputter targets and other components, performs to such targets, and the like). In part, the present invention relates to methods to prepare metal material having desirable characteristics (e.g., texture, grain size, and the like) and further relates to the product itself. In particular, a method of making a sputtering target is described and involves providing a slab containing at least one metal. This slab is subjected to a first rolling to form an intermediate plate, wherein the first rolling can include a plurality of rolling passes. The method further involves dividing the intermediate plate into a plurality of sub-lot plates; and subjecting one or more of the sub-lot plates to a second rolling to form a metal plate, wherein the second rolling can include a plurality of rolling passes, and wherein each of the rolling passes of the second rolling imparts a true strain reduction of about 0.1 or more, and more preferably about 0.15 or more, and even more preferably about 0.2 or more. The final rolling pass of the second rolling can impart a true strain reduction that is equivalent to or greater than a true strain reduction imparted by other rolling passes. At least one of the rolling passes of the second rolling can be in a transverse direction relative to at least one of the rolling passes of the first rolling. The rolling passes of the second rolling can be multi-directional. The rolling steps can be cold rolling or warm rolling or hot rolling or various combinations of these rolling steps. The definition of true strain is e=Ln(ti/tf), where e is the true strain or true strain reduction, ti is the initial thickness of the plate, tf is the final thickness of the plate, and Ln is the natural log of the ratio.

Further, the present invention relates to a method of producing high purity tantalum plates (or other types of metal plates) of sufficient size to yield a plurality of sputtering target blanks or components. Preferably, the metal (e.g., tantalum) has a fine, uniform microstructure. For example, the metal, such as the valve metal, can have an average grain size of about 20 microns or less, such as 18 microns or less, or 15 microns or less, and a texture that is substantially void of (100) texture bands. For purposes of the present invention, tantalum metal is discussed throughout the present application for strictly exemplary purposes, realizing that the present invention equally applies to other metals, including other valve metals and other metals.

The method first involves the processing of a tantalum ingot into a rectangular form suitable for deformation processing. The ingot can be commercially available. The ingot can be prepared in accordance with the teachings of Michaluk et al., U.S. Pat. No. 6,348,113, incorporated herein by reference. The method may also include directly casting the high purity tantalum metal into a form suitable for deformation processing or can form the slab by electron beam melting. The rectangular form is to be of sufficient size and volume to produce a multitude of sputtering target blanks. The rectangular form must also have sufficient thickness to permit for the attainment of necessary amounts of work (e.g., cold working) during processing to achieve the proper annealing response and avoid the formation of a marbilized surface. For example, a rectangular form having a dimension of 5 inches by 10.25 inches by a length of greater than 30 inches would be suitable. The rectangular form may be optionally thermally treated (e.g., annealed) one or more times in a protective environment to achieve stress relief, partial recrystallization, or full recrystallization.

Next, the rectangular form is processed to produce a rolling slab or bar having rolling faces that are flat and parallel. It is preferred that the roll faces be processed in a manner that does not contaminate or embed foreign materials into the surface. Machining methods such as milling or fly cutting are the preferred method for making the rolling faces flat and parallel. Other methods such as blanchard grinding or lapping may be used, and subsequent cleaning operations, such as heavy pickling, may be used to remove the about 0.001″from all surfaces to remove any embedded contaminants. At this point, and strictly as an example only, the machined slab can have a thickness of from about 3 to about 6 inches, a width of from about 9 to about inches, and a length of from about 18 to about 48 inches. Preferably, the machined slab has a thickness of 4.5 inches, a width of 10.25 inches, a length of 30 inches, with rolling faces, preferably, with two opposing rolling surfaces that are flat within 0.020 inches. Other dimensions for purposes of the present invention may be used.

The machined slab can then be cleaned to remove any foreign matter atop the surfaces such as oil and/or oxide residues. An acid pickle solution of hydrofluoric acid, nitric acid, and deionized water such as described in U.S. Pat. 6,348,113 would suffice. The slabs can then be annealed in vacuum or an inert atmosphere at a temperature between 700-1500° C. or 850-1500° C. for about 30 minutes to about 24 hours, and more preferably at a temperature of from about 1050 to about 1300° C. for 2-3 hours, to achieve stress relief, or partial or complete recrystallization without excessive non-uniform grain growth or secondary recrystallization.

Each slab is then rolled (e.g., cold rolled, warm rolled, hot rolled) to produce a plate of desired gauge and size to yield a multitude of sputtering target blanks in accordance to the following criteria. The slab is rolled to form an intermediate plate having a thickness between that of the slab and the desired finished plate. For example, the intermediate plate can have a thickness of from about 0.75 to about 1.5 inches. The thickness of the intermediate plate, such that the true strain imparted in rolling from intermediate gauge to finished, is about 0.1 or more, and preferably about 0.15 or more, or 0.2 or more, such as from about 0.25 to about 2.0, and preferably from about 0.5 to about 1.5 of the total true strain imparted in rolling the slab to intermediate gauge. The final rolling of the second rolling can impart a true strain reduction that is equal to or greater than a true strain reduction imparted by any other rolling pass. For example, for cold rolling of a 4.5″ slab into a finished plate having a thickness of 0.360″ represents a total true strain reduction of 2.52; a finished plate rolled from an intermediate plate having a thickness of 1.125″ would have a true strain imparted in rolling from intermediate gauge to finished of 0.63 of the true strain imparted when rolling from slab to intermediate plate. Likewise, a finished plate rolled from an intermediate plate having a thickness of 0.950″ would have a true strain imparted in rolling from intermediate gauge to finished of 0.442 of the true strain imparted when rolling from slab to intermediate plate. For purposes of the present invention, each rolling step described in the present invention can be a cold rolling step, a warm rolling step, or a hot rolling step. Furthermore, each rolling step can comprise one or more rolling steps wherein if more than one rolling step is used in a particular step, the multiple rolling steps can be all cold rolling, warm rolling, or hot rolling, or can be a mixture of various cold rolling, warm rolling, or hot rolling steps. These terms are understood by those skilled in the art. Cold rolling is typically at ambient or lower temperatures during rolling, whereas warm rolling is typically slightly above ambient temperatures such as 10° C. to about 25° C above ambient temperatures whereas hot rolling is typically 25° C. or higher above ambient temperatures. Also, for purposes of the present invention, prior to any working of the metal or after any working of the metal (e.g., rolling and the like), the metal material can be thermally treated (e.g., annealed) one or more times (e.g., 1, 2, 3 or more times) in each working step. This thermal treatment can achieve stress release, or partial or complete recrystallization.

In rolling of large slab to intermediate plate, it is often not practical nor is it necessary to take heavy strain reductions with each rolling pass to attain uniform work in the intermediate plate. One purpose of rolling from slab to intermediate plate is to produce an intermediate form by a controlled and repeatable process. The intermediate form is to be of sufficient size to be cut into one or more sections that can then be rolled to finish plates of sufficient size to yield a multitude of sputtering target blanks. It is preferred to control the process so that the rate of reduction from slab to intermediate plate is repeatable from slab to slab, and so that the amount of lateral spread of the slab is limited to optimize the yield of product from the slab. Should the length of the work piece be spread beyond an allowable limit, then it would be difficult to roll the intermediate plate to the target gauge range and concurrently attain the minimum width necessary to optimize product yield. Preferably, the intermediate plate has a length that is greater than the length of the slab by about 10%.

The process of rolling slab to intermediate plate begins with taking small reductions per each rolling pass. For instance, see Tables 1-24 herein. While the rolling schedule for rolling slab to intermediate plate can be defined to target a desired true strain reduction per pass, such an approach would be difficult and time consuming to implement, monitor, and verify compliance. A more preferred approach is to roll slab to intermediate plate using a rolling schedule defined by changes in mill gap settings. See Tables 1-24 herein. The process would begin with taking one or two “sizing passes” to reach a predefined mill gap setting, then reducing the mill gap by a predetermined amount per pass. The change in mill gap setting with each roll pass can be held constant, increased sequentially, or increased incrementally. As the thickness of the work piece approaches the target thickness for the intermediate plate, the change in mill gap setting may be changed per the mill operator discretion in order to attain the desired intermediate plate width and thickness range.

Care must be taken to limit the amount of lateral spread of the work piece when rolling slab to intermediate plate. Lateral spreading can occur by taking flattening passes, so the number of flattening passes and the amount of strain imparted per flattening pass should be minimized. Also, feeding of the work piece into the mill at an angle should be avoided. The use of a pusher bar to feed the work piece into the mill is desired.

The intermediate plate can be optionally annealed at a temperature from about 700-1500° C. or from about 850 to about 1500° C. for about 30 minutes to about 24 hours, and more preferably at a temperature of from about 1050 to about 1300° C. for 1-3 hours or more, to achieve stress relief, or partial or complete recrystallization without excessive non-uniform grain growth or secondary recrystallization. Other times and temperatures can be used.

The primary objective of rolling intermediate plate to finished plate is to impart sufficient true strain per pass to attain homogeneous strain through the thickness of the plate necessary to attain a fine and uniform grain structure and texture in the material after annealing. Specifically, it is desirable to impart a minimum of 0.2 true strain reduction in each rolling pass in reducing the intermediate plate thickness to finished plate thickness. To facilitate heavy rolling reductions, the intermediate plate is cut into sub-lot plates having a width that is smaller than the intermediate plate and equal to or slightly greater than the diameter of the sputter target blank. Furthermore, it is desirable that roll direction during the heavy reduction rolling process be perpendicular to the rolling direction of the intermediate plate. However, straight rolling from slab to finished plate, or clock rolling of intermediate plate to finished plate is permissible.

Each sub-lot of intermediate plate is then rolled (e.g., cold rolled) into finished plate of desired dimensions using a rolling schedule having a defined minimum true strain per pass. To assure process and product consistency from lot to lot, it is preferred that that the number of heavy reduction passes, and the allowable true strain reduction range of each pass be predefined (for example, as shown in Tables 1-24). Also, to prevent excessive curving of the plate after rolling, it is beneficial that the last rolling pass impart a true strain reduction greater than the prior rolling passes. An example of a schedule to roll intermediate plate to final product is as follows: intermediate plate lots having a thickness range of 0.950-1.00″ can be rolled to a target gauge of 0.360″ by four reduction passes of 0.2-0.225 strain per pass, plus a fifth reduction pass having a true strain reduction of 0.2 or greater.

With respect to the slab, intermediate plate, sub-lot plates, plates, the sputtering target, and any other components including the ingot, these materials can have any purity with respect to the metal present. For instance, the purity can be 95% or higher, such as at least 99%, at least 99.5%, at least 99.9%, at least 99.95%, at least 99.99%, at least 99.995% or at least 99.999% pure with respect to the metal present. For instance, these purities would apply to a tantalum metal slab, wherein the slab would be 99% pure tantalum and so on with respect to the higher purities. Furthermore, the starting slab can have any grain size such as 2000 microns or less and more preferably 1000 microns or less and more preferably 500 microns or less even more preferably 150 microns or less.

Furthermore, with respect to the texture of the starting slab or the ingot in which the slab is typically made from, as well as the other subsequent components resulting from the working of the slab such as the intermediate plate, sub-lot plates, the texture can be any texture such as a primary (100) or primary (111) texture or a mixed (111):(100) texture on the surface and/or throughout the thickness of the material, such as the slab. Preferably, the material, such as the slab, does not have any textural banding, such as (100) textural banding when the texture is a primary (111) or mixed (111):(100) texture.

With respect to the metal, preferably the metal processed in the present invention is a valve metal or refractory metal but other metals could also be used. Specific examples of the type of metals that can be processed with the present invention include, but are not limited to, tantalum, niobium, copper, titanium, gold, silver, cobalt, and alloys thereof.

In one embodiment of the present invention, the product resulting from the process of the present invention preferably results in plates or sputter targets wherein at least 95% of all grains present are 100 microns or less, or 75 microns or less, or 50 microns or less, or 35 microns or less, or 25 microns or less. More preferably, the product resulting from the process of the present invention results in plates or sputter targets wherein at least 99% of all grains present are 100 microns or less or 75 microns or less or 50 microns or less and more preferably 35 microns or less and even more preferably 25 microns or less. Preferably, at least 99.5% of all grains present have this desired grain structure and more preferably at least 99.9% of all grains present have this grain structure, that is 100 microns or less, 75 microns or less, 50 microns or less and more preferably 35 microns or less and even more preferably 25 microns or less. The determination of this high percentage of low grain size is preferably based on measuring 500 grains randomly chosen on a microphotograph showing the grain structure.

Preferably, the valve metal plate has a primary (111) or primary (100) or a mixed (111) (100) texture on the surface and/or a transposed primary (111), a transposed primary (100) or a mixed transposed (111) (100) throughout its thickness.

In addition, the plate (as well as the sputter target) are preferably produced wherein the product is substantially free of marbleizing on the surface of the plate or target. The substantially free of marbleizing preferably means that 25% or less of the surface area of the surface of the plate or target does not have marbleizing, and more preferably 20% or less, 15% or less, 10% or less, 5% or less, 3% or less, or 1% or less of the surface area of the surface of the plate or target does not have marbleizing. Typically, the marbleizing is a patch or large banding area which contains texture that is different from the primary texture. For instance, when a primary (111) texture is present, the marbleizing in the form of a patch or large banding area will typically be a (100) texture area which is on the surface of the plate or target and may as well run throughout the thickness of the plate or target. This patch or large banding area can generally be considered a patch having a surface area of at least 0.25% of the entire surface area of the plate or target and may be even larger in surface area such as 0.5% or 1%, 2%, 3%, 4%, or 5% or higher with respect to a single patch on the surface of the plate or target. There may certainly be more than one patch that defines the marbleizing on the surface of the plate or target. Using the non-destructive banding test referred to above in U.S. patent application Ser. No. 60/545,617, the present application can confirm this quantitatively. Further, the plate or target can have banding (% banding area) of 1% or less, such as 0.60 to 0.95%. The present invention serves to reduce the size of the individual patches showing marbleizing and/or reduces the number of overall patches of marbleizing occurring. Thus, the present invention minimizes the surface area that is affected by marbleizing and reduces the number of marbleizing patches that occur. By reducing the marbleizing on the surface of the plate or target, the plate or target does not need to be subjected to further working of the plate or target and/or further annealing. In addition, the top surface of the plate or target does not need to be removed in order to remove the marbleizing effect. Thus, by way of the present invention, less physical working of the plate or target is needed thus resulting in labor cost as well as savings with respect to loss of material. In addition, by providing a product with less marbleizing, the plate and more importantly, the target can be sputtered uniformly and without waste of material.

The metal plate of the present invention can have a surface area that has less than 75%, such as less than 50% or less than 25%, of lusterous blotches after sputter or chemical erosion. Preferably, the surface area has less than 10% of lusterous blotches after sputter or chemical erosion. More preferably, the surface area has less than 5% of lusterous blotches, and most preferably, less than I% of lusterous blotches after sputter or chemical reacting.

For purposes of the present invention, the texture can also be a mixed texture such as a (111):(100) mixed texture and this mixed texture is preferably uniform throughout the surface and/or thickness of the plate or target. The various uses including formation of thin films, capacitor cans, capacitors, and the like as described in U.S. Pat. No. 6,348,113 can be achieved here and to avoid repeating, these uses and like are incorporated herein. Also, the uses, the grain sizes, texture, purity that are set forth in U.S. Pat. No. 6,348,113 can be used herein for the metals herein and are incorporated herein in their entirety.

The metal plate of the present invention can have an overall change in pole orientation (i). The overall change in pole orientation can be measured through the thickness of the plate in accordance with U.S. Pat. No. 6,462,339. The method of measuring the overall change in pole orientation can be the same as a method for quantifying the texture homogeneity of a polycrystalline material. The method can include selecting a reference pole orientation, scanning in increments a cross-section of the material or portion thereof having a thickness with scanning orientation image microscopy to obtain actual pole orientations of a multiplicity of grains in increments throughout the thickness, determining orientation differences between the reference pole orientation and actual pole orientations of a multiplicity of grains in the material or portion thereof, assigning a value of misorientation from the references pole orientation at each grain measured throughout the thickness, and determining an average misorientation of each measured increment throughout the thickness; and obtaining texture banding by determining a second derivative of the average misorientation of each measured increment through the thickness. Using the method described above, the overall change in pole orientation of the metal plate of the present invention measured through the thickness of the plate can be less than about 50/mm. Preferably, the overall change in pole orientation measured through the thickness of the plate of the present invention, in accordance to U.S. Pat. No. 6,462,339 is less than about 25/mm, more preferably, less than about 10/mm, and, most preferably, less than about 5/mm.

The metal plate of the present invention, can have a scalar severity of texture inflection (A) measured through the thickness of the plate in accordance with U.S. Pat. No. 6,462,339. The method can include selecting a reference pole orientation, scanning in increments a cross-section of the material or portion thereof having a thickness with scanning orientation image microscopy to obtain actual pole orientations of a multiplicity of grains in increments throughout the thickness, determining orientation differences between the reference pole orientation and actual pole orientations of a multiplicity of grains in the material or portion thereof, assigning a value of misorientation from the references pole orientation at each grain measured throughout said thickness, and determining an average misorientation of each measured increment throughout the thickness; and determining texture banding by determining a second derivative of the average misorientation of each measured increment through the thickness. The scalar severity of texture inflection of the metal plate of the present invention measured through the thickness of the plate can be less than about 5/mm. Preferably, the scalar severity of texture inflection measured through the thickness of the plate in accordance with U.S. Pat. No. 6,462,339 is less than about 4/mm, more preferably, less than about 2/mm, and, most preferably, less than about 1/mm.

The present invention will be further clarified by the following examples, which are intended to be purely exemplary of the present invention. The true strain in % in the Tables can be converted by dividing by 100 to obtain the units used in the present specification above.

### EXAMPLE 1

A tantalum ingot having been formed into a slab using conventional forging steps had starting dimensions as set forth in Table 1. The starting thickness prior to each milling step is also set forth in Table 1. The desired true strain per pass as well as the desired post pass thickness are the true strain and post pass thickness desired by each subsequent rolling step. The actual post pass thickness and actual mill stretch are the result of measurements resulting from the rolling steps. The reduction in thickness signifies a rolling step which was a cold rolling step. C and D are two different ingots that were formed into slabs with the indicated dimensions. The C-split and D-split signify where the intermediate plate was cut into sub-lot plates. One of these plates was then subsequently subjected to further rolling as indicated in Table 1.

### EXAMPLE 2

Example 1 was repeated accept the rolling schedule in Table 2, showing various starting thicknesses and subsequent reduction in thicknesses by cold rolling.

### EXAMPLE 3

In this Example, Example 1 was essentially followed except for the noted differences set forth in Tables 3a and 3b. The split I and split 2 signify the sub-lot plates that were formed from the intermediate plate. Individual rolling of the sub-lot plates was conducted as signified by the data set forth in Tables 3a and 3b. At certain points in the process, the intermediate plate was subjected to a flatten pass which was where the intermediate plate was turned 90° and put through the same roller mill without adjusting the setting to flatten any waves in the metal. The data resulting from this schedule of rolling is set forth in Tables 3a and 3b.

### EXAMPLE 4

Example 4 is another experiment following the procedures of Example 1 except for the noted differences.

### EXAMPLE 5

Example 5 is an example of what settings should be used depending upon the starting thickness and the desired reductions per pass. This Table shows what the mill gap settings would be for each reduction and the actual thickness achieved. As can be seen from these Examples, a sub-lot plate which can be subsequently formed into a sputtering target can be made wherein preferably, the rolling of the sub-lot plates imparts a true strain reduction of about 0.1 or more and more preferably about a true strain reduction of about 0.2 or more.

### EXAMPLE 6

Tables 6-24 are further examples of tantalum slabs that were subjected to the rolling schedules set forth in these Tables. Each Table is an individual experiment of a separate slab.

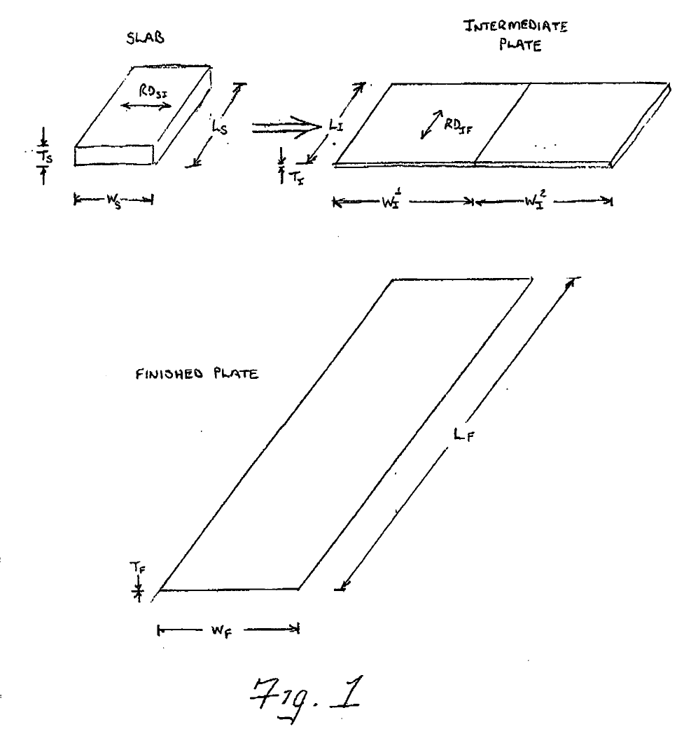

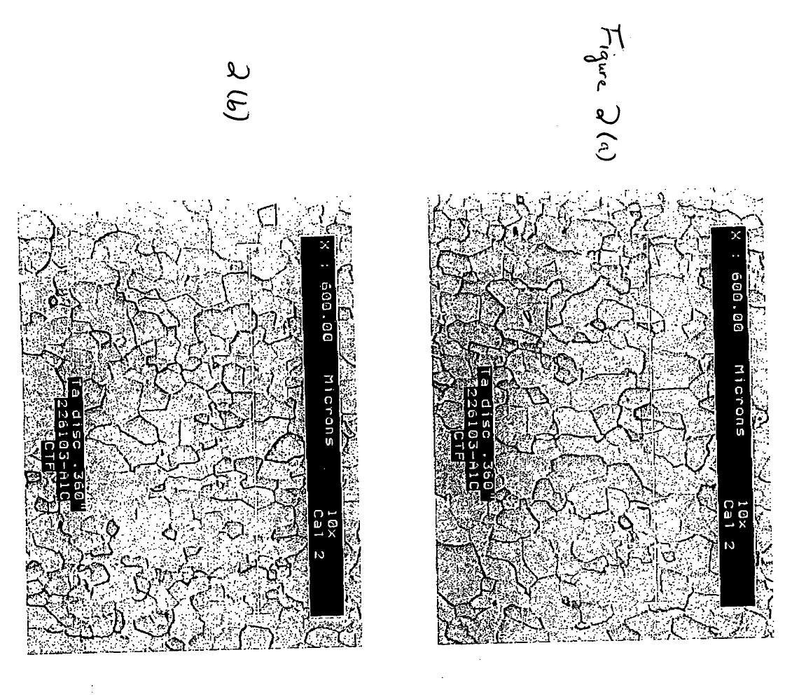

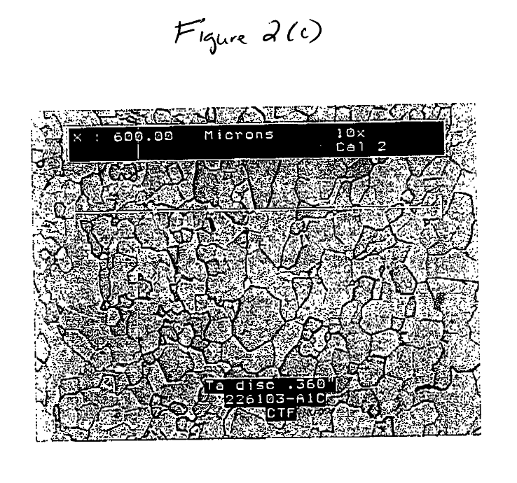

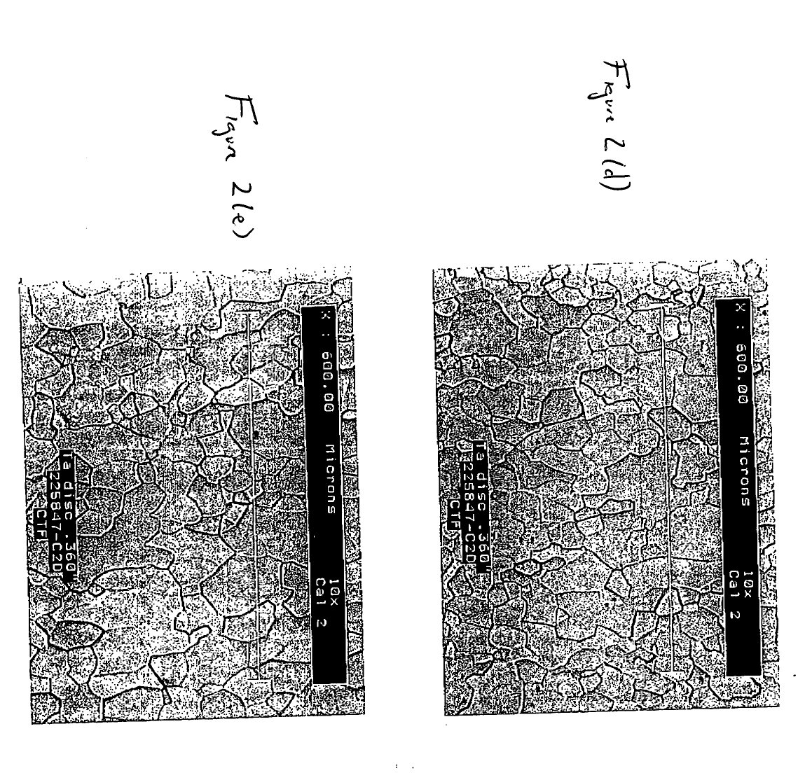

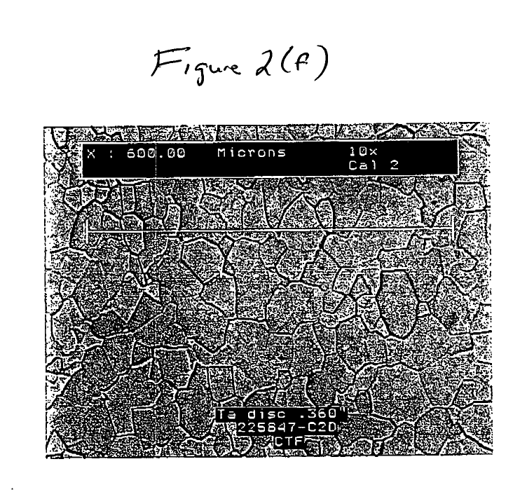

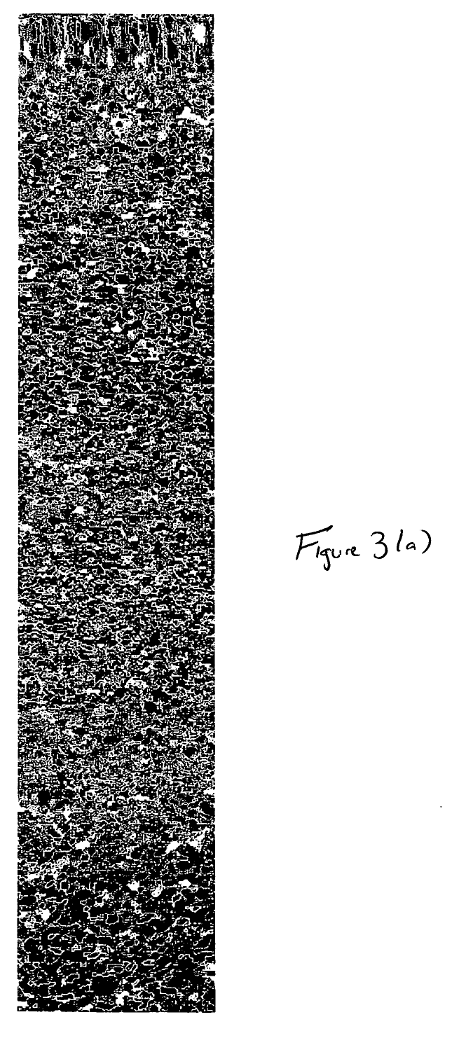

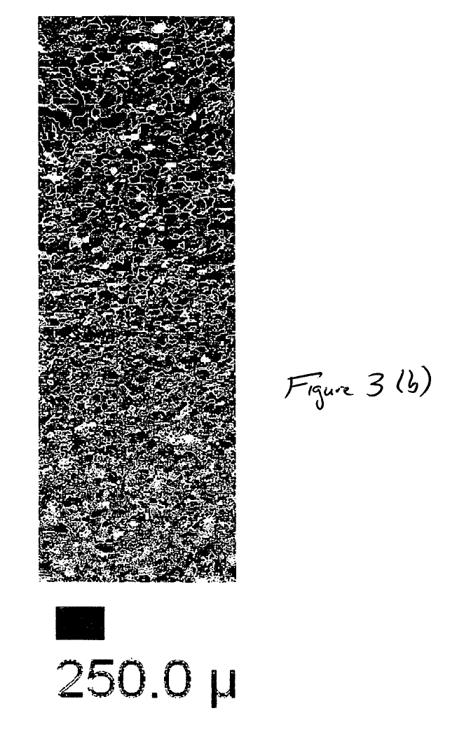

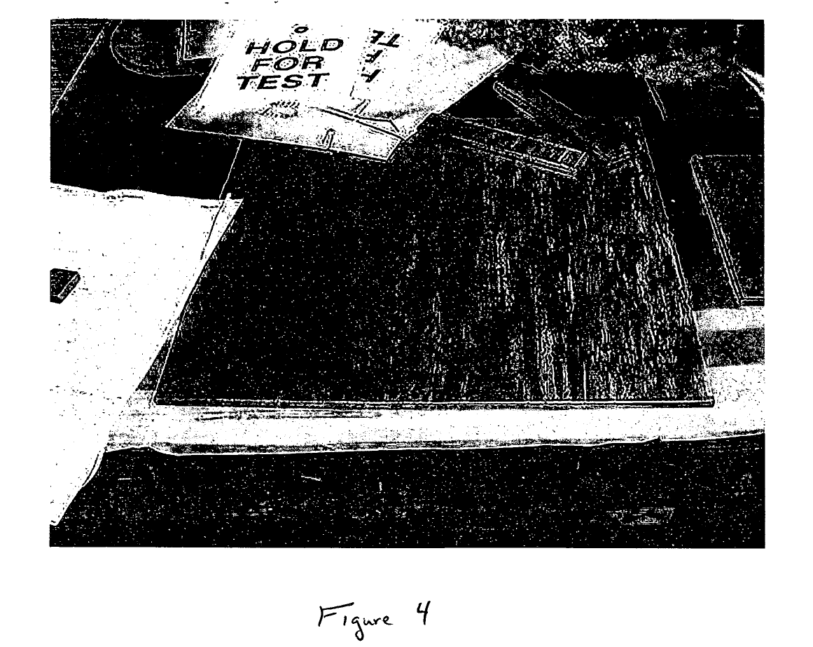

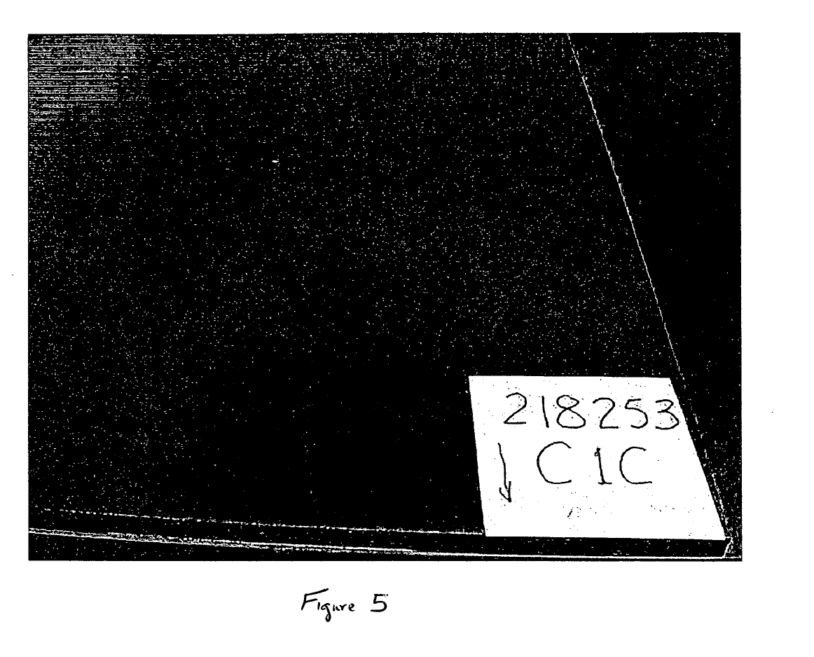

FIG. 1 sets forth the dimensions referred to herein for length and width. FIG. 2(a)-(f) are photomicrographs of two finished plates from the Examples showing uniform and low grain size. FIG. 3 is a IPF of an annealed finished plate from one of the Examples, as determined using the same procedure as U.S. Pat. No. 6,348,113. The IPF shows a uniform primary mixed (111):(100) texture with no textural banding. FIG. 4 is a color picture of a commercially available plate showing marbleizing on the surface. Note the non-uniform appearance. On the other hand, FIG. 5 is a color picture of a finished plate from one of the Examples of the present invention. Note the uniform surface appearance showing no marbleizing.

The claims show additional embodiments of the present invention. Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

TABLE 1

| | | | | | mill | | | | | | |
|---|---|---|---|---|---|---|---|---|---|---|---|
| | | | desired | Desired | stretch | | Actual | Actual | separating | | Post pass |
| Starting | | Starting | true strain | post pass | compen- | Mill gap | post pass | mill | force (% of | Actual true | dimensions |
| L × W | Ingot #-/ | thickness | per pass | thickness | sation | setting | thickness | stretch | 2500 tons) | strain/pass | L × W × t |
| 27 5/16 × | C | 3.6 | −0.04 | 3.46 | 0.05 | 3.41 | 3.517 | 0.107 | 54 | −0.0233255 | |
| 10½ | | | | | | | | | | | |
| | | 3.517 | −0.04 | 3.38 | 0.12 | 3.26 | 3.396 | 0.136 | x | −0.0350101 | |
| | | 3.396 | −0.04 | 3.26 | 0.12 | 3.143 | 3.275 | 0.132 | 64 | −0.0362804 | |
| | | 3.275 | −0.04 | 3.15 | 0.10 | 3.046 | 3.174 | 0.128 | 63 | −0.0313252 | |
| | | 3.174 | −0.04 | 3.05 | 0.10 | 2.949 | 3.074 | 0.125 | 61 | −0.032013 | |
| | | 3.074 | −0.04 | 2.95 | 0.12 | 2.838 | 2.956 | 0.118 | 60 | −0.0391426 | |
| | | 2.956 | −0.04 | 2.84 | 0.13 | 2.71 | 2.831 | 0.121 | 61 | −0.043207 | |
| | | 2.831 | −0.04 | 2.72 | 0.12 | 2.6 | 2.722 | 0.122 | 48 | −0.0392631 | |
| | | 2.722 | −0.04 | 2.62 | 0.12 | 2.494 | 2.604 | 0.11 | 53 | −0.0443182 | |
| | | 2.604 | −0.04 | 2.50 | 0.12 | 2.379 | 2.488 | 0.109 | 54 | −0.0455695 | |
| | | 2.488 | −0.04 | 2.39 | 0.14 | 2.25 | 2.364 | 0.114 | 55 | −0.0511241 | |
| | | 2.364 | −0.04 | 2.27 | 0.13 | 2.14 | 2.25 | 0.11 | 53 | −0.0494249 | |
| | | 2.25 | −0.078 | 2.08 | 0.16 | 1.92 | 2.047 | 0.127 | 63 | −0.0945549 | |
| | | 2.047 | −0.078 | 1.89 | 0.16 | 1.733 | 1.848 | 0.115 | 56 | −0.1022713 | |
| | | 1.848 | −0.078 | 1.71 | 0.15 | 1.56 | 1.677 | 0.117 | 60 | −0.0970975 | |
| | | 1.677 | −0.078 | 1.55 | 0.13 | 1.42 | 1.517 | 0.097 | 49 | −0.1002718 | |
| | | 1.517 | −0.078 | 1.40 | 0.10 | 1.303 | 1.4 | 0.097 | 52 | −0.0802625 | |
| | | 1.4 | −0.078 | 1.29 | 0.18 | 1.118 | 1.285 | 0.167 | 50 | −0.0857135 | 30.75 × |
| | | | | | | | | | | | 27.5 × 1.285 |
| 15⅜ × | C-split | 1.285 | −0.12413 | 1.135 | 0.100 | 1.035 | x | x | x | x | |
| 27.5 | | | | | | | | | | | |
| | | x | −0.13668 | 0.990 | 0.100 | 0.89 | x | x | x | x | |
| | | x | −0.11892 | 0.879 | 0.100 | 0.779 | 0.91 | x | x | x | |
| | | 0.91 | −0.12851 | 0.773 | 0.100 | 0.673 | x | x | x | x | |
| | | x | −0.12819 | 0.680 | 0.100 | 0.58 | 0.7 | 0.12 | x | x | |
| | | 0.7 | −0.1285 | 0.598 | 0.100 | 0.498 | 0.61 | 0.112 | x | −0.1376214 | |
| | | 0.61 | −0.25586 | 0.463 | 0.140 | 0.323 | 0.47 | 0.147 | x | −0.2607263 | |
| | | 0.47 | −0.25162 | 0.360 | 0.145 | 0.215 | 0.37 | 0.155 | x | −0.2392297 | 27.5 × ( 53) |
| 27⅜ × | D/ | 3.58 | −0.04 | 3.440 | 0.03 | 3.41 | 3.517 | 0.107 | 46 | −0.0177544 | |
| 10½ | | | | | | | | | | | |
| | | 3.517 | −0.04 | 3.379 | 0.12 | 3.26 | 3.392 | 0.132 | 67 | −0.0361886 | |
| | | 3.392 | −0.04 | 3.259 | 0.12 | 3.143 | 3.275 | 0.132 | 65 | −0.0351018 | |
| | | 3.275 | −0.04 | 3.147 | 0.10 | 3.046 | 3.174 | 0.128 | 64 | −0.0313252 | |
| | | 3.174 | −0.04 | 3.050 | 0.10 | 2.949 | 3.074 | 0.125 | 62 | −0.032013 | |
| | | 3.074 | −0.04 | 2.953 | 0.12 | 2.838 | 2.959 | 0.121 | 63 | −0.0381283 | |
| | | 2.959 | −0.04 | 2.843 | 0.13 | 2.71 | 2.831 | 0.121 | 58 | −0.0442214 | |
| | | 2.831 | −0.04 | 2.720 | 0.12 | 2.6 | 2.717 | 0.117 | 55 | −0.0411017 | |
| | | 2.717 | −0.04 | 2.610 | 0.12 | 2.494 | 2.604 | 0.11 | 47 | −0.0424796 | |
| | | 2.604 | −0.04 | 2.502 | 0.12 | 2.379 | 2.486 | 0.107 | 54 | −0.0463737 | |
| | | 2.486 | −0.04 | 2.389 | 0.14 | 2.25 | 2.364 | 0.114 | 54 | −0.0503199 | |
| | | 2.364 | −0.04 | 2.271 | 0.13 | 2.14 | 2.244 | 0.104 | 55 | −0.0520951 | |
| | | 2.244 | −0.078 | 2.076 | 0.16 | 1.92 | 2.047 | 0.127 | 36 | −0.0918847 | |
| | | 2.047 | −0.078 | 1.893 | 0.16 | 1.733 | 1.843 | 0.11 | 55 | −0.1049806 | |
| | | 1.843 | −0.078 | 1.705 | 0.14 | 1.56 | 1.677 | 0.117 | 61 | −0.0943882 | |
| | | 1.677 | −0.078 | 1.551 | 0.13 | 1.42 | 1.538 | 0.118 | 58 | −0.0865236 | |
| | | 1.538 | −0.078 | 1.423 | 0.12 | 1.303 | 1.4 | 0.097 | 43 | −0.0940106 | |
| | | 1.4 | −0.078 | 1.295 | 0.18 | 1.118 | 1.288 | 0.17 | x | −0.0833816 | |
| | | 1.288 | −0.078 | 1.191 | 0.11 | 1.079 | 1.155 | 0.076 | x | −0.1089903 | |
| | | 1.155 | −0.078 | 1.068 | 0.08 | 0.988 | 1.09 | 0.102 | 50 | −0.0579226 | |
| | | 1.09 | −0.078 | 1.008 | 0.10 | 0.907 | 1.017 | 0.11 | x | −0.0693206 | 41 × 27.5 × |
| | | | | | | | | | | | 1.017 |
| 20.5 × 27.5 | D split | 1.017 | −0.13 | 0.893 | 0.11 | 0.786 | 0.896 | 0.11 | 52 | −0.126672 | |
| | | 0.896 | −0.13 | 0.787 | 0.11 | 0.676 | 0.781 | 0.105 | 52 | −0.1373653 | |
| | | 0.781 | −0.13 | 0.686 | 0.12 | 0.561 | 0.671 | 0.11 | 53 | −0.151806 | |
| | | 0.671 | −0.13 | 0.589 | 0.07 | 0.516 | 0.594 | 0.078 | x | −0.1218898 | |
| | | 0.594 | −0.25 | 0.463 | 0.19 | 0.277 | 0.44 | 0.163 | 81 | −0.3001046 | |
| | | 0.44 | −0.2 | 0.360 | 0.12 | 0.24 | 0.371 | 0.131 | x | −0.1705727 | |

TABLE 2

| | | | | | | | | | separating | | |
|---|---|---|---|---|---|---|---|---|---|---|---|
| | | | desired | | mill | | | | force | | |
| | | | true | Desired | stretch | Mill | Actual | Actual | (% of | | Post pass |
| Starting | Ingot | Starting | strain per | post pass | compen- | gap | post pass | mill | 2500 | Actual true | dimensions |
| L × W | #-/ | thickness | pass | thickness | sation | setting | thickness | stretch | tons) | strain/pass | L × W × t |
| | | 4.605 | −0.0205 | 4.512 | 0.120 | 4.392 | | | | | |
| | | 4.51 | −0.0205 | 4.420 | 0.125 | 4.295 | | | | | |
| | | 4.42 | −0.0205 | 4.330 | 0.130 | 4.200 | | | | | |
| | | 4.33 | −0.0205 | 4.242 | 0.110 | 4.132 | | | | | |
| | | 4.24 | −0.0205 | 4.156 | 0.110 | 4.046 | | | | | |
| | | 4.16 | −0.0205 | 4.072 | 0.110 | 3.962 | | | | | |
| | | 4.07 | −0.0205 | 3.989 | 0.110 | 3.879 | | | | | |
| | | 3.99 | −0.0205 | 3.908 | 0.110 | 3.798 | | | | | |
| | | 3.91 | −0.0205 | 3.829 | 0.110 | 3.719 | | | | | |
| | | 3.83 | −0.0205 | 3.751 | 0.110 | 3.641 | | | | | |
| | | 3.75 | −0.0205 | 3.675 | 0.110 | 3.565 | | | | | |
| | | 3.68 | −0.0205 | 3.601 | 0.110 | 3.491 | | | | | |
| | | 3.60 | −0.0205 | 3.528 | 0.110 | 3.418 | | | | | |
| 27 5/16 × | C | 3.6 | −0.04 | 3.46 | 0.05 | 3.41 | 3.517 | 0.107 | 54 | −0.0233255 | |
| 10½ | | | | | | | | | | | |
| | | 3.517 | −0.04 | 3.38 | 0.12 | 3.26 | 3.396 | 0.136 | x | −0.0350101 | |
| | | 3.396 | −0.04 | 3.26 | 0.12 | 3.143 | 3.275 | 0.132 | 64 | −0.0362804 | |
| | | 3.275 | −0.04 | 3.15 | 0.10 | 3.046 | 3.174 | 0.128 | 63 | −0.0313252 | |
| | | 3.174 | −0.04 | 3.05 | 0.10 | 2.949 | 3.074 | 0.125 | 61 | −0.032013 | |
| | | 3.074 | −0.04 | 2.95 | 0.12 | 2.838 | 2.956 | 0.118 | 60 | −0.0391426 | |
| | | 2.956 | −0.04 | 2.84 | 0.13 | 2.71 | 2.831 | 0.121 | 61 | −0.043207 | |
| | | 2.831 | −0.04 | 2.72 | 0.12 | 2.6 | 2.722 | 0.122 | 48 | −0.0392631 | |
| | | 2.722 | −0.04 | 2.62 | 0.12 | 2.494 | 2.604 | 0.11 | 53 | −0.0443182 | |
| | | 2.604 | −0.04 | 2.50 | 0.12 | 2.379 | 2.488 | 0.109 | 54 | −0.0455695 | |
| | | 2.488 | −0.04 | 2.39 | 0.14 | 2.25 | 2.364 | 0.114 | 55 | −0.0511241 | |
| | | 2.364 | −0.04 | 2.27 | 0.13 | 2.14 | 2.25 | 0.11 | 53 | −0.0494249 | |
| | | 2.25 | −0.078 | 2.08 | 0.16 | 1.92 | 2.047 | 0.127 | 63 | −0.0945549 | |
| | | 2.047 | −0.078 | 1.89 | 0.16 | 1.733 | 1.848 | 0.115 | 56 | −0.1022713 | |
| | | 1.848 | −0.078 | 1.71 | 0.15 | 1.56 | 1.677 | 0.117 | 60 | −0.0970975 | |
| | | 1.677 | −0.078 | 1.55 | 0.13 | 1.42 | 1.517 | 0.097 | 49 | −0.1002718 | |
| | | 1.517 | −0.078 | 1.40 | 0.10 | 1.303 | 1.4 | 0.097 | 52 | −0.0802625 | |
| | | 1.4 | −0.078 | 1.29 | 0.18 | 1.118 | 1.285 | 0.167 | 50 | −0.0857135 | 30.75 × |
| | | | | | | | | | | | 27.5 × 1.285 |
| 15⅜ × | C-split | 1.285 | −0.12413 | 1.135 | 0.100 | 1.035 | x | x | x | x | |
| 27.5 | | | | | | | | | | | |
| | | x | −0.13668 | 0.990 | 0.100 | 0.89 | x | x | x | x | |
| | | x | −0.11892 | 0.879 | 0.100 | 0.779 | 0.91 | x | x | x | |
| | | 0.91 | −0.12851 | 0.773 | 0.100 | 0.673 | x | x | x | x | |
| | | x | −0.12819 | 0.680 | 0.100 | 0.58 | 0.7 | 0.12 | x | x | |
| | | 0.7 | −0.1285 | 0.598 | 0.100 | 0.498 | 0.61 | 0.112 | x | −0.1376214 | |
| | | 0.61 | −0.25586 | 0.463 | 0.140 | 0.323 | 0.47 | 0.147 | x | −0.2607263 | |
| | | 0.47 | −0.25162 | 0.360 | 0.145 | 0.215 | 0.37 | 0.155 | x | −0.2392297 | 27.5 × (53) |
| 27⅜ × | D/ | 3.58 | −0.04 | 3.440 | 0.03 | 3.41 | 3.517 | 0.107 | 46 | −0.0177544 | |
| 10½ | | | | | | | | | | | |
| | | 3.517 | −0.04 | 3.379 | 0.12 | 3.26 | 3.392 | 0.132 | 67 | −0.0361886 | |
| | | 3.392 | −0.04 | 3.259 | 0.12 | 3.143 | 3.275 | 0.132 | 65 | −0.0351018 | |
| | | 3.275 | −0.04 | 3.147 | 0.10 | 3.046 | 3.174 | 0.128 | 64 | −0.0313252 | |
| | | 3.174 | −0.04 | 3.050 | 0.10 | 2.949 | 3.074 | 0.125 | 62 | −0.032013 | |
| | | 3.074 | −0.04 | 2.953 | 0.12 | 2.838 | 2.959 | 0.121 | 63 | −0.0381283 | |
| | | 2.959 | −0.04 | 2.843 | 0.13 | 2.71 | 2.831 | 0.121 | 58 | −0.0442214 | |
| | | 2.831 | −0.04 | 2.720 | 0.12 | 2.6 | 2.717 | 0.117 | 55 | −0.0411017 | |
| | | 2.717 | −0.04 | 2.610 | 0.12 | 2.494 | 2.604 | 0.11 | 47 | −0.0424796 | |
| | | 2.604 | −0.04 | 2.502 | 0.12 | 2.379 | 2.486 | 0.107 | 54 | −0.0463737 | |
| | | 2.486 | −0.04 | 2.389 | 0.14 | 2.25 | 2.364 | 0.114 | 54 | −0.0503199 | |
| | | 2.364 | −0.04 | 2.271 | 0.13 | 2.14 | 2.244 | 0.104 | 55 | −0.0520951 | |
| | | 2.244 | −0.078 | 2.076 | 0.16 | 1.92 | 2.047 | 0.127 | 36 | −0.0918847 | |
| | | 2.047 | −0.078 | 1.893 | 0.16 | 1.733 | 1.843 | 0.11 | 55 | −0.1049806 | |
| | | 1.843 | −0.078 | 1.705 | 0.14 | 1.56 | 1.677 | 0.117 | 61 | −0.0943882 | |
| | | 1.677 | −0.078 | 1.551 | 0.13 | 1.42 | 1.538 | 0.118 | 58 | −0.0865236 | |
| | | 1.538 | −0.078 | 1.423 | 0.12 | 1.303 | 1.4 | 0.097 | 43 | −0.0940106 | |
| | | 1.4 | −0.078 | 1.295 | 0.18 | 1.118 | 1.288 | 0.17 | x | −0.0833816 | |
| | | 1.288 | −0.078 | 1.191 | 0.11 | 1.079 | 1.155 | 0.076 | x | −0.1089903 | |
| | | 1.155 | −0.078 | 1.068 | 0.08 | 0.988 | 1.09 | 0.102 | 50 | −0.0579226 | |
| | | 1.09 | −0.078 | 1.008 | 0.10 | 0.907 | 1.017 | 0.11 | x | −0.0693206 | 41 × 27.5 × |
| | | | | | | | | | | | 1.017 |
| 20.5 × | D split | 1.017 | −0.13 | 0.893 | 0.11 | 0.786 | 0.896 | 0.11 | 52 | −0.126672 | |
| 27.5 | | | | | | | | | | | |
| | | 0.896 | −0.13 | 0.787 | 0.11 | 0.676 | 0.781 | 0.105 | 52 | −0.1373653 | |
| | | 0.781 | −0.13 | 0.686 | 0.12 | 0.561 | 0.671 | 0.11 | 53 | −0.151806 | |
| | | 0.671 | −0.13 | 0.589 | 0.07 | 0.516 | 0.594 | 0.078 | x | −0.1218898 | |
| | | 0.594 | −0.25 | 0.463 | 0.19 | 0.277 | 0.44 | 0.163 | 81 | −0.3001046 | |
| | | 0.44 | −0.2 | 0.360 | 0.12 | 0.24 | 0.371 | 0.131 | x | −0.1705727 | |

TABLE 3a

| | | Desired | | | | | | Separating | Actual | | |
|---|---|---|---|---|---|---|---|---|---|---|---|
| | | true | Desired | | Mill | Actual | Actual | force (% | true | | Actual |
| | Starting | stain per | post pass | Mill stretch | gap | post pass | mill | of 2500 | stain/ | | Minus |
| Ingot #-/ | thickness | pass | thickness | compensation | setting | thickness | stretch | tons) | pass | Comment | target |
| | 4.605 | −0.0205 | 4.512 | 0.120 | 4.392 | 4.520 | 0.128 | 64 | −1.9% | | 0.008 |
| 811B Slab | 4.51 | −0.0205 | 4.420 | 0.125 | 4.295 | 4.410 | 0.115 | 75 | −2.5% | | −0.010 |
| | 4.42 | −0.0205 | 4.330 | 0.130 | 4.200 | 4.362 | 0.162 | 74 | −1.1% | | 0.032 |
| | 4.33 | −0.0205 | 4.242 | 0.110 | 4.132 | 4.292 | 0.160 | 78 | −1.6% | | 0.050 |

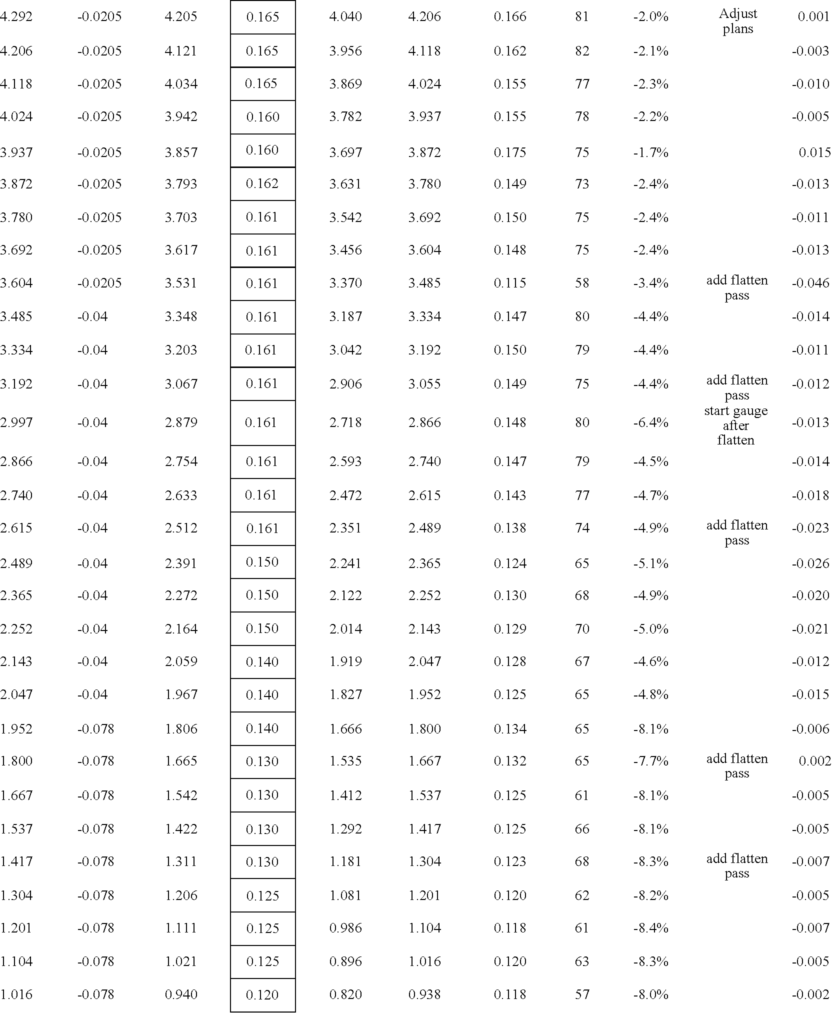

| | | | | | | | | | | | |
|---|---|---|---|---|---|---|---|---|---|---|---|
| Split 1 | 0.938 | −0.12 | 0.832 | 0.100 | 0.732 | 0.835 | 0.103 | 50 | −11.6% | 19″ wide | 0.003 |
| 811B1 | 0.835 | −0.12 | 0.741 | 0.110 | 0.631 | 0.737 | 0.106 | 46 | −12.5% | | −0.004 |
| | 0.737 | −0.12 | 0.654 | 0.110 | 0.544 | 0.645 | 0.101 | 45 | −13.3% | | −0.009 |
| | 0.645 | −0.12 | 0.572 | 0.100 | 0.472 | 0.569 | 0.097 | 42 | −12.5% | | −0.003 |
| | 0.569 | −0.12 | 0.505 | 0.100 | 0.405 | 0.497 | 0.092 | 42 | −13.5% | | −0.008 |
| | 0.497 | −0.12 | 0.441 | 0.090 | 0.351 | 0.440 | 0.089 | 41 | −12.2% | | −0.001 |
| | 0.440 | −0.12 | 0.390 | 0.090 | 0.300 | 0.386 | 0.086 | 37 | −13.1% | Stopped at | −0.004 |
| | | | | | | | | | | this gauge | |

TABLE 3b

| | | | | | | | | | | | |
|---|---|---|---|---|---|---|---|---|---|---|---|
| Split 2 | 0.938 | −0.2 | 0.768 | 0.100 | 0.668 | 0.793 | 0.125 | 60 | −16.8% | | 0.025 |
| Set plan and run | 0.768 | −0.2 | 0.629 | 0.100 | 0.529 | 0.648 | 0.119 | 57 | −20.2% | | 0.019 |
| 811B2 | 0.629 | −0.2 | 0.515 | 0.100 | 0.415 | 0.529 | 0.114 | 54 | −20.3% | | 0.014 |
| | 0.515 | −0.2 | 0.421 | 0.100 | 0.321 | 0.434 | 0.113 | 53 | −19.8% | | 0.013 |
| | 0.421 | −0.2 | 0.345 | 0.100 | 0.245 | 0.351 | 0.106 | 50 | −21.2% | .351 | 0.006 |
| | | | | | | | | | | to | |
| | | | | | | | | | | .355 | |

TABLE 4

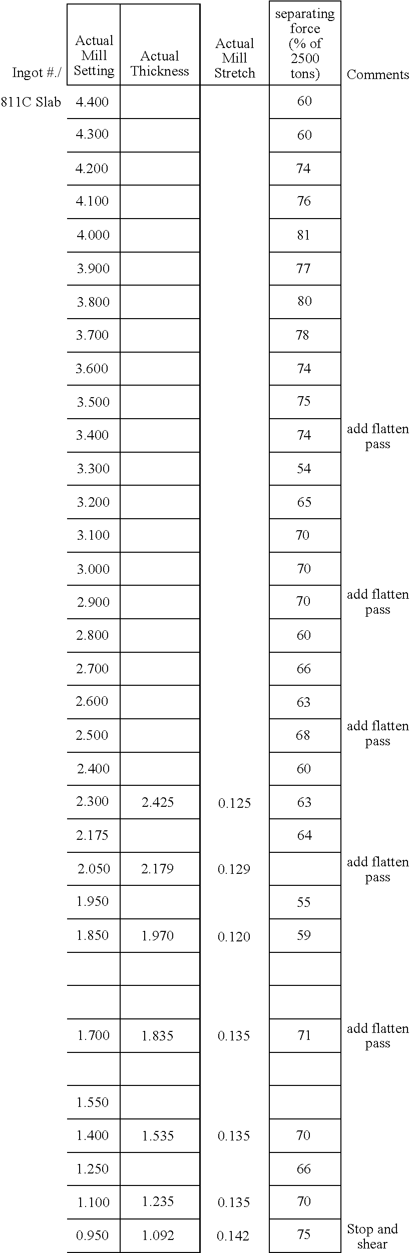

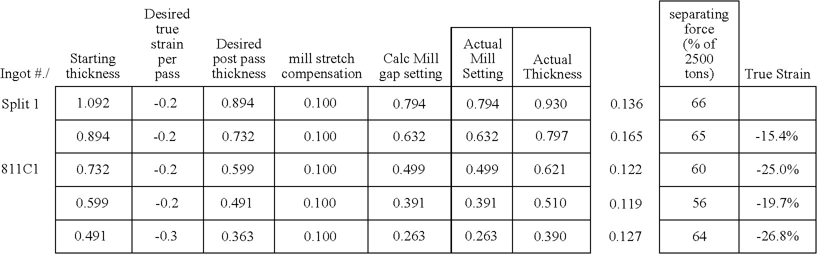

TABLE 5

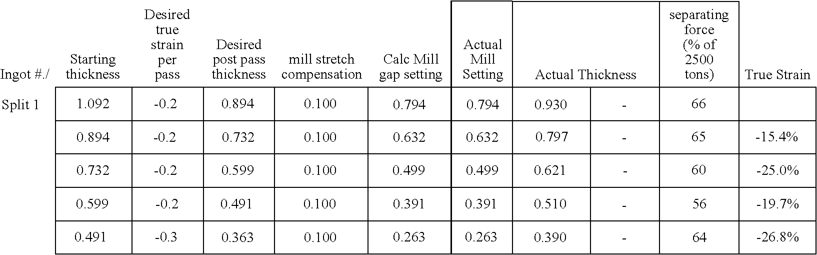

| | | | | | | | | | | | |
|---|---|---|---|---|---|---|---|---|---|---|---|
| Red per pass | −22.5% | −22.2% | −21.8% | −20.0% | −20.0% | −20.0% | −20.0% | −20.0% | −20.0% | −20.0% | −20.0% |
| Red per pass | −22.5% | −22.2% | −21.8% | −20.0% | −20.0% | −20.0% | −20.0% | −20.0% | −20.0% | −20.0% | −20.0% |
| Red per pass | −22.5% | −22.2% | −21.8% | −20.0% | −20.0% | −20.0% | −20.0% | −20.0% | −20.0% | −20.0% | −20.0% |
| Red per pass | −22.5% | −22.2% | −21.8% | −20.0% | −20.0% | −20.0% | −20.0% | −20.0% | −20.0% | −20.0% | −20.0% |
| Red per pass | −22.5% | −22.2% | −21.8% | −20.0% | −20.0% | −20.0% | −20.0% | −20.0% | −20.0% | −20.0% | −20.0% |
| Thickness | 1.120 | 1.100 | 1.080 | 1.060 | 1.040 | 1.020 | 1.000 | 0.980 | 0.960 | 0.940 | 0.920 |
| | A | B | A | B | A | B | A | B | A | B | A |
| Mill Gap 1 | 0.894 | 0.881 | 0.868 | 0.868 | 0.851 | 0.835 | 0.819 | 0.802 | 0.786 | 0.770 | 0.753 |
| Mill Gap 2 | 0.714 | 0.706 | 0.698 | 0.711 | 0.697 | 0.684 | 0.670 | 0.657 | 0.644 | 0.630 | 0.617 |
| Mill Gap 3 | 0.570 | 0.566 | 0.561 | 0.582 | 0.571 | 0.560 | 0.549 | 0.538 | 0.527 | 0.516 | 0.505 |
| Mill Gap 4 | 0.455 | 0.453 | 0.451 | 0.476 | 0.467 | 0.458 | 0.449 | 0.440 | 0.431 | 0.422 | 0.413 |
| Mill Gap 5 | 0.363 | 0.363 | 0.363 | 0.390 | 0.383 | 0.375 | 0.368 | 0.361 | 0.353 | 0.346 | 0.338 |

TABLE 6
Typical mill settings for broadside rolling of plate
Rolling direction

| Broadside | Mill set |
|---|---|
| 1 | 4.5 |
| 2 | 4.4 |
| 3 | 4.3 |
| 4 | 4.2 |
| 5 | 4.1 |
| 6 | 4 |
| 7 | 3.9 |
| 8 | 3.8 |
| 9 | 3.7 |
| 10 | 3.6 |
| 11 | 3.5 |
| 12 | 3.4 |
| 13 | 3 |
| 14 | 3.2 |
| 15 | 3.1 |
| 16 | 3 |
| 17 | 2.9 |
| 18 | 2.8 |
| 19 | 2.7 |
| 20 | 2.6 |
| 21 | 2.5 |
| 22 | 2.4 |
| 23 | 2.3 |
| 24 | 2.2 |
| 25 | 2.1 |
| 26 | 2 |
| 27 | 1.9 |
| 28 | 1.8 |
| 29 | 1.7 |
| 30 | 1.65 |
| 31 | 1.51 |
| 32 | 1.36 |
| 33 | 1.23 |
| 34 | 1.1 |
| 35 | 0.97 |
| 36 | 0.84 |

TABLE 7

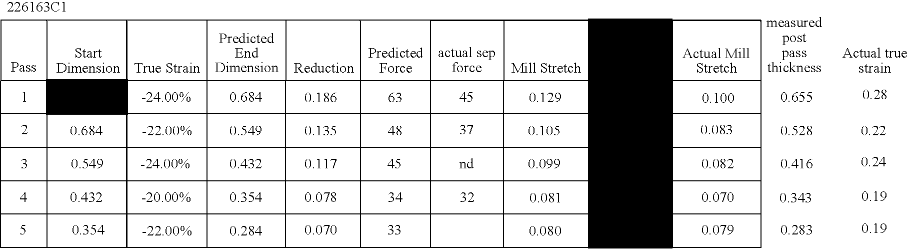

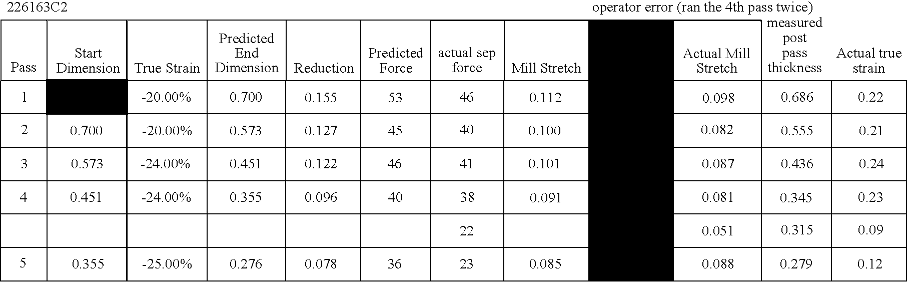

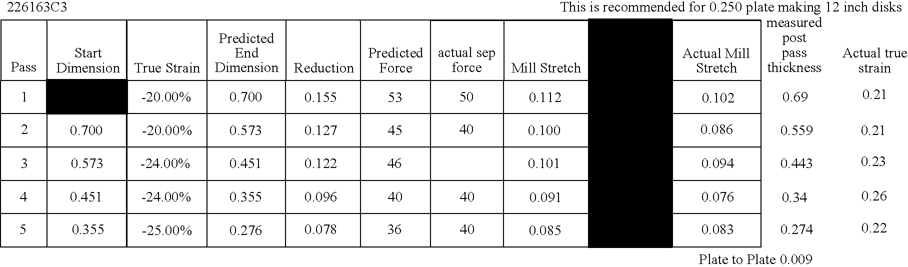

TABLE 8

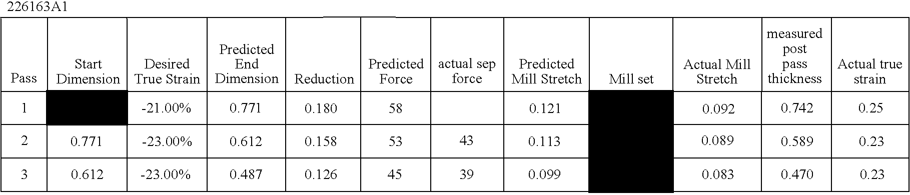

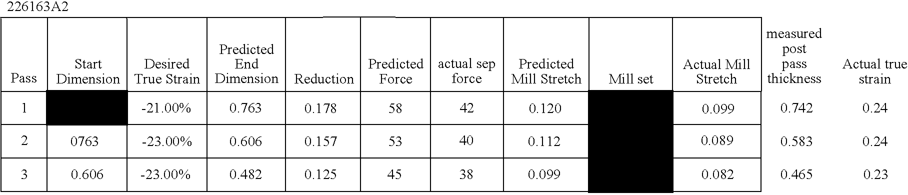

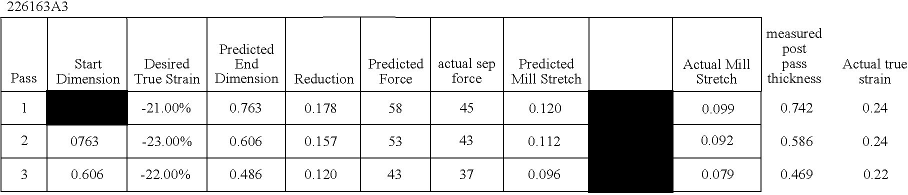

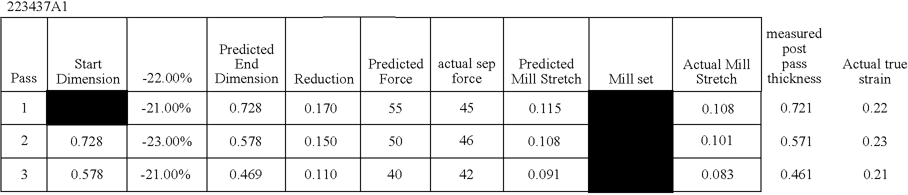

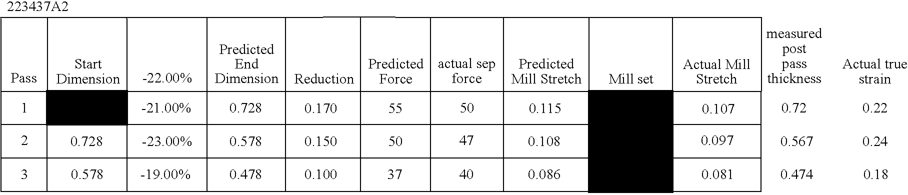

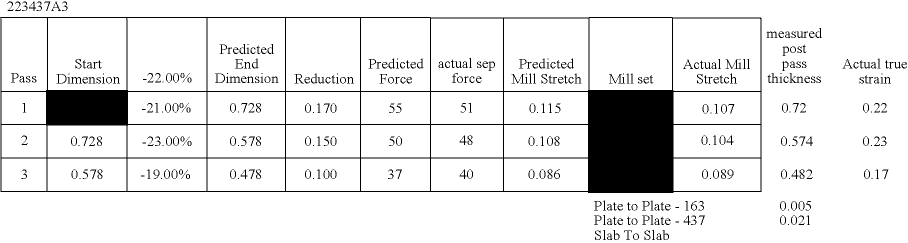

TABLE 9

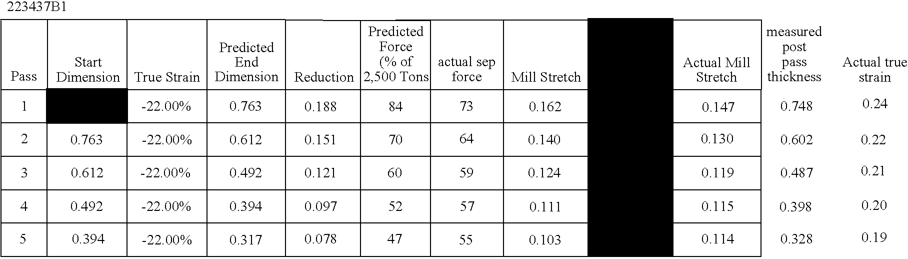

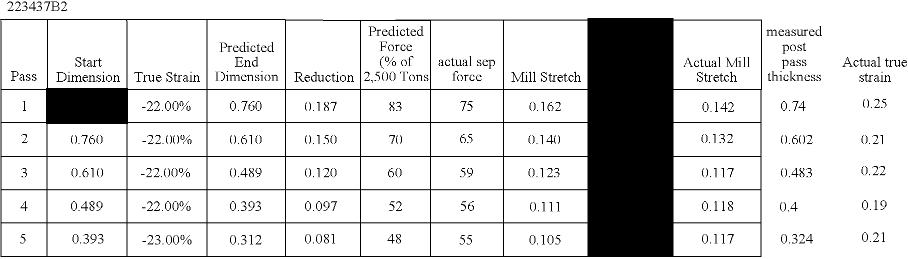

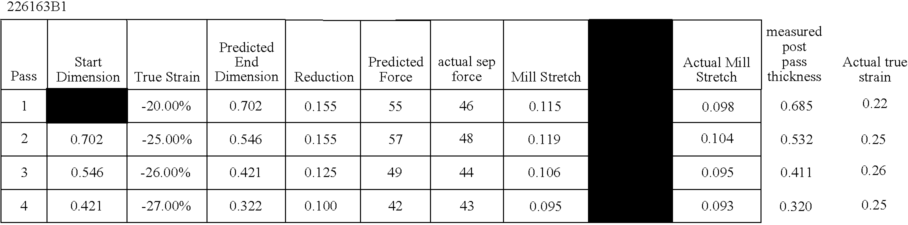

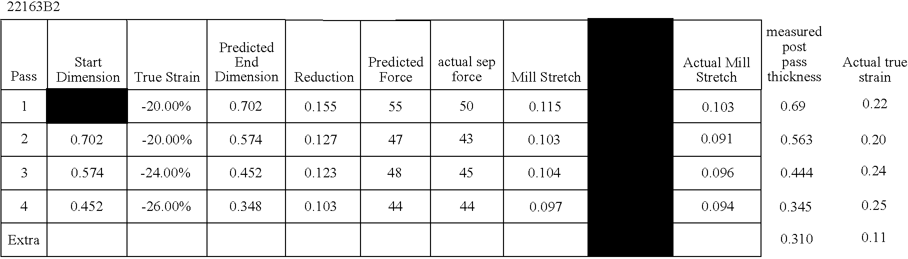

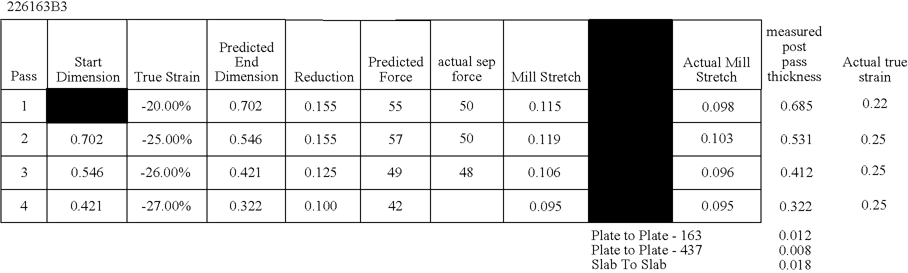

TABLE 10

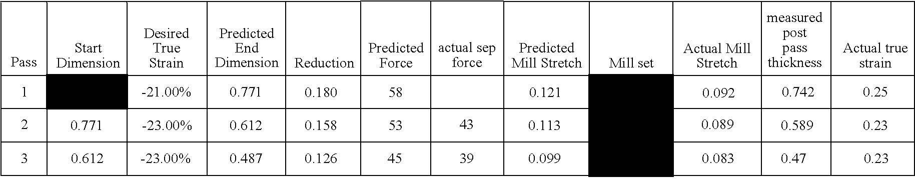

TABLE 11

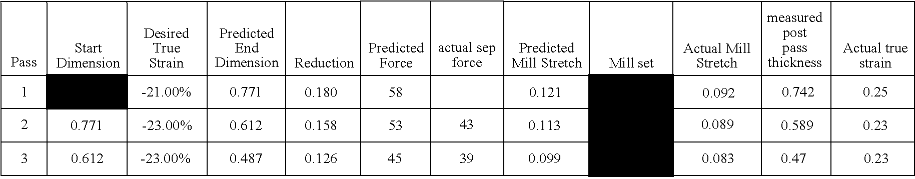

TABLE 12

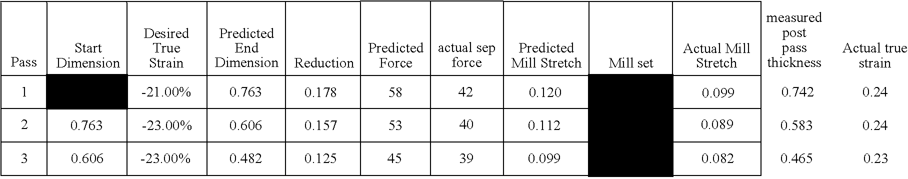

TABLE 13

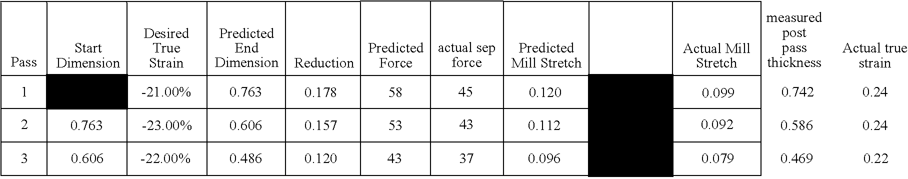

TABLE 14

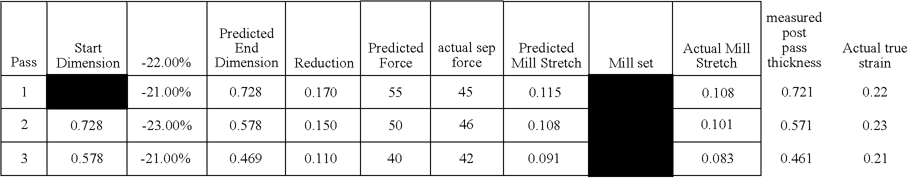

TABLE 15

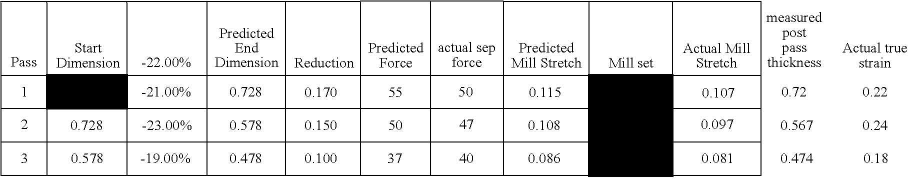

TABLE 16

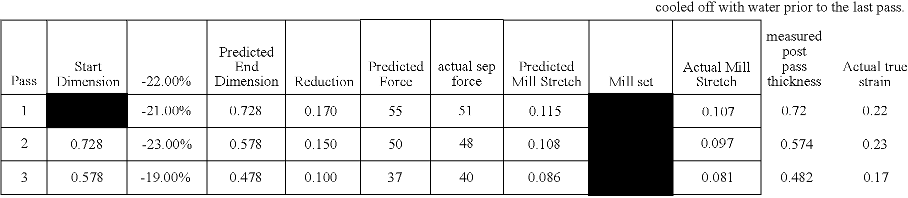

TABLE 17

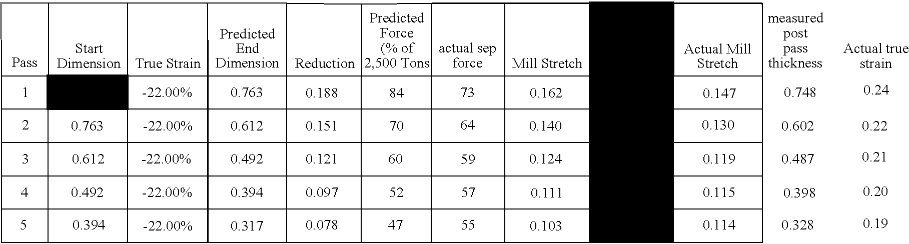

TABLE 18

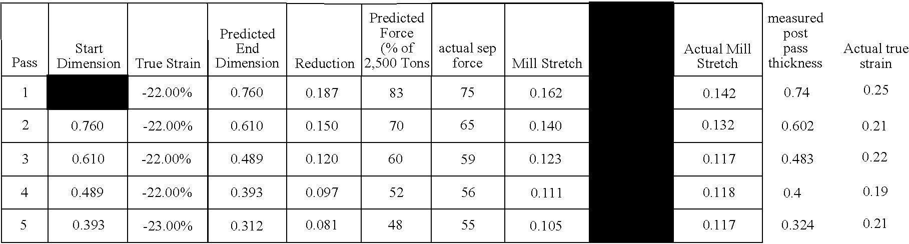

TABLE 19

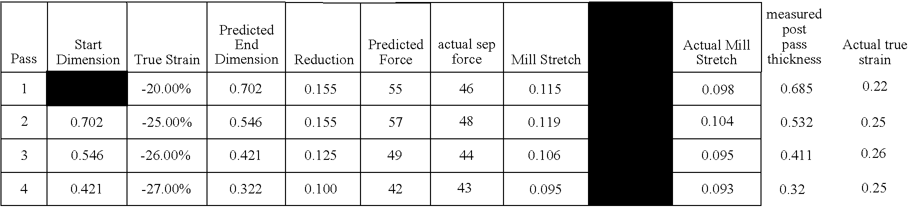

TABLE 20

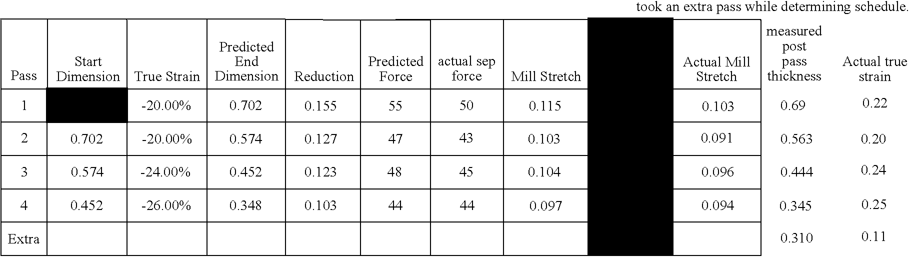

TABLE 21

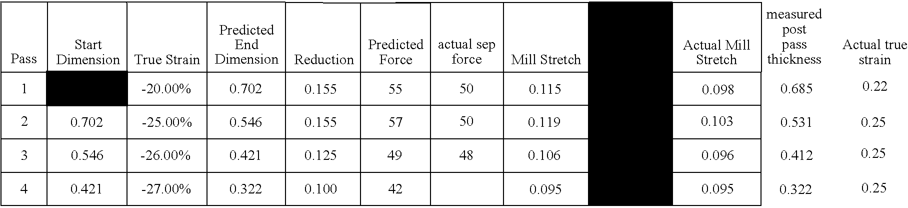

TABLE 22

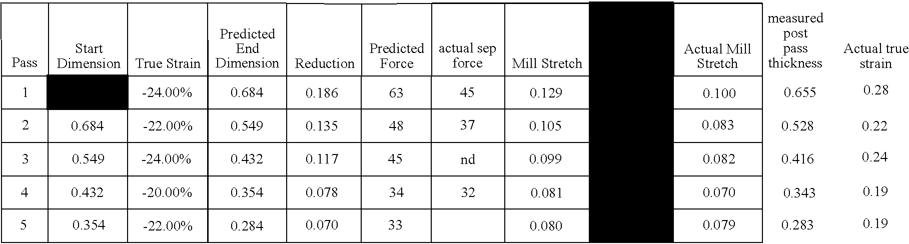

TABLE 23

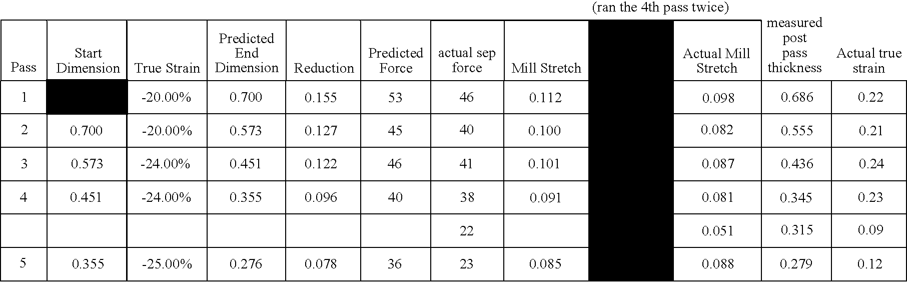

TABLE 24

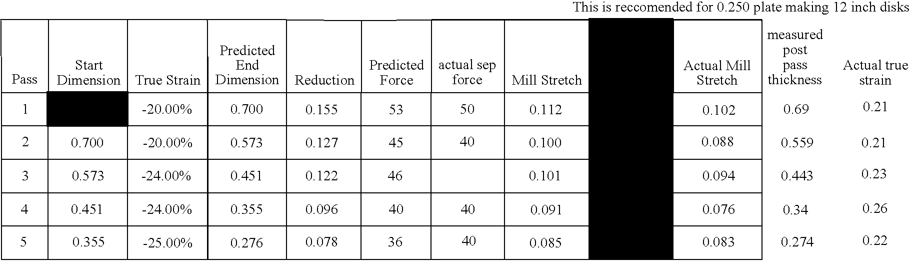

1. A method of making a sputtering target, comprising:
providing a slab comprising at least one metal;
a first rolling of said slab to form an intermediate plate, wherein said first rolling includes a plurality of rolling passes;
dividing said intermediate plate into a plurality of sub-lot plates; and
a second rolling of at least one of said sub-lot plates to form a metal plate, wherein said second rolling includes a plurality of rolling passes, and wherein each of said rolling passes of said second rolling imparts a true strain reduction of about 0.2 or more.

2. The method of claim 1, wherein a true strain reduction imparted by said second rolling is from about 0.25 to about 2.0 of a true strain reduction imparted by said first rolling.

3. (canceled)

4. The method of claim 1, wherein said first rolling comprises a rolling schedule defined by changes in mill gap settings.

5. The method of claim 1, wherein a final rolling pass of said second rolling imparts a true strain reduction that is equal to or greater than a true strain reduction imparted by any other rolling pass.

6. The method of claim 1, wherein said at least one metal is niobium, tantalum, or an alloy thereof.

7. The method of claim 1, wherein said at least one metal is copper or titanium or alloys thereof.

8. The method of claim 1, further comprising annealing said slab.

9. The method of claim 8, wherein said annealing is under vacuum or inert conditions at a temperature of from about 70° to about 1500° C. for a time of from about 30 minutes to about 24 hours.

10. The method of claim 1, further comprising providing said slab with two opposing rolling surfaces that are flat to within about 0.02 inches.

11-13. (canceled)

14. The method of claim 1, wherein said intermediate plate has a thickness of from about 0.75 to about 1.5 inches.

15. The method of claim 1, wherein said intermediate plate has a length that is greater than a length of said slab by about 10% or less.

16. The method of claim 1, further comprising annealing said intermediate plate.

17. The method of claim 16, wherein said annealing is under vacuum or inert conditions at a temperature of from about 700 to about 1500° C. for a time of from about 30 minutes to about 24 hours.

18. The method of claim 1, wherein at least one of said rolling passes of said second rolling is in a transverse direction relative to at least one of said rolling passes of said first rolling.

19. The method of claim 1, wherein said rolling passes of said second rolling are multi-directional.

20. A metal plate formed by the method of claim 1.

21. The metal plate of claim 20, wherein said valve metal plate has an average grain size of 20 microns or less.

22-23. (canceled)

24. The metal plate of claim 20, wherein 95% of the grains have a diameter of less than 100 micron.

25-29. (canceled)

30. The metal plate of claim 20, wherein said valve metal plate is substantially free of surface marbleizing.

31-34. (canceled)

35. The metal plate of claim 20, wherein surface area is comprised of less than 5% of lusterous blotches after sputter or chemical erosion.

36. (canceled)

37. The metal plate of claim 20, wherein said valve metal plate has a texture that is substantially void of textural bands.

38. The metal plate of claim 20, wherein said valve metal plate has a uniform texture throughout a thickness thereof.

39. The metal plate of claim 20, wherein said valve metal plate has a primary (111), a primary (100), or a mixed (111) (100) texture on the surface and/or a transposed primary (111), a transposed primary (100), or a mixed transposed (111) (100) throughout a thickness thereof.

40. The metal plate of claim 20, wherein the overall change in pole orientation (Q) measured through the thickness of the plate is less than 50/mm, as measured by:
selecting a reference pole orientation;
scanning in increments a cross-section of said plate or portion thereof having a thickness with scanning orientation image microscopy to obtain actual pole orientations of a multiplicity of grains in increments throughout said thickness;
determining orientation differences between said reference pole orientation and actual pole orientations of a multiplicity of grains in said plate or portion thereof;
assigning a value of misorientation from said references pole orientation at each grain measured throughout said thickness;
determining an average misorientation of each measured increment throughout said thickness; and
obtaining texture banding by dete2rmining a second derivative of said average misorientation of each measured increment through said thickness, is less than 50/mm.

41-43. (canceled)

44. The metal plate of claim 20, wherein the scalar severity of texture inflection (A) measured through the thickness of the plate is less than 5/mm as measured by:
selecting a reference pole orientation;
scanning in increments a cross-section of said plate or portion thereof having a thickness with scanning orientation image microscopy to obtain actual pole orientations of a multiplicity of grains in increments throughout said thickness;
determining orientation differences between said reference pole orientation and actual pole orientations of a multiplicity of grains in said plate or portion thereof, assigning a value of misorientation from said references pole orientation at each grain measured throughout said thickness;
determining an average misorientation of each measured increment throughout said thickness; and
obtaining texture banding by determining a second derivative of said average Disorientation of each measured increment through said thickness, is less than 5/mm.

45-47. (canceled)

48. A sputtering component formed from a metal plate of claim 20.

49-51. (canceled)
